(19) United States
(12) Patent Application Publication
(10) Pub. No.: US 2026/0237348 A1
(43) Pub. Date: Aug. 13, 2026

(54) FREQUENCY VARIABLE DISPLAY APPARATUS

(71) Applicant: LG Display Co., Ltd., Seoul (KR)

(72) Inventors: Soek Min CHOI, Paju-si (KR); Moo Kyoung HONG, Paju-si (KR)

(73) Assignee: LG Display Co., Ltd., Seoul (KR)

(21) Appl. No.: 19/422,907

(22) Filed: Dec. 17, 2025

(30) Foreign Application Priority Data
Jan. 21, 2025 (KR) 10-2025-0008786

(51) Int. Cl. G09G 3/3233; G09G 3/00

(52) U.S. Cl. CPC G09G 3/3233; G09G 3/006; G09G 2300/0819; G09G 2300/0852; G09G 2310/08; G09G 2320/0247; G09G 2320/045; G09G 2320/048; G09G 2330/12; G09G 2340/0435

(57) ABSTRACT

A display apparatus includes a subpixel including a driving transistor having a gate electrode connected to a first node and a source electrode connected to a second node, a light emitting element having an anode electrode connected to the second node, and a storage capacitor having one electrode connected to the first node and another electrode connected to the second node, a data line configured to transfer a data voltage to the first node in a gate-source setting period, and a reference voltage line configured to transfer an initialization voltage to the second node in the gate-source setting period. A voltage level of the initialization voltage increases as the light emitting element is degraded.

### CROSS-REFERENCE TO RELATED APPLICATIONS

This application claims the benefit of and priority to Korean Patent Application No. 10-2025-0008786 filed on Jan. 21, 2025, the entire contents of which are incorporated herein by reference for all purposes.

### BACKGROUND

### 1. Technical Field

The present disclosure relates to a frequency variable display apparatus.

### 2. Description of Related Art

Frequency variable display apparatuses vary a frame frequency of an image displayed on a screen, based on an attribute of video data received from an external video source. Frequency variable display apparatuses support a variable refresh rate (VRR) function which varies a frame frequency within a predetermined frequency range.

When a frame frequency is rapidly changed from a low-speed frame to a high-speed frame or to be opposite thereto by a VRR operation, a flicker phenomenon caused by a recognition luminance deviation may be recognized by a user. To decrease the recognition luminance deviation, luminance algorithm technology which adjusts a data gain according to a frame frequency has been known. However, in such technology, because a data gain of a current frame is determined based on frequency information about a previous frame, there is a limitation in decreasing a recognition luminance deviation (i.e., VRR flicker) between a first frame immediately after a frame frequency is rapidly changed and a frame immediately before the first frame.

The description of related art should not be considered prior art merely because it is mentioned in or associated with this section. The description of related art includes information that describes one or more aspects of the subject technology, and the description in this section does not limit the scope of the present disclosure.

### SUMMARY

To overcome the problems of the related art, one or more aspects of the present disclosure may provide a frequency variable display apparatus which may decrease VRR flicker occurring in a rapid change condition of a frame frequency.

To achieve these aspects and other advantages and in accordance with the purpose of the disclosure, as embodied and broadly described herein, in one or more aspects, a frequency variable display apparatus includes: a subpixel including a driving transistor having a gate electrode connected to a first node and a source electrode connected to a second node, a light emitting element having an anode electrode connected to the second node, and a storage capacitor having one electrode connected to the first node and another electrode connected to the second node; a data line configured to transfer a data voltage to the first node in a gate-source setting period; and a reference voltage line configured to transfer an initialization voltage to the second node in the gate-source setting period, wherein a voltage level of the initialization voltage increases as the light emitting element is degraded.

In another aspect of the present disclosure, a frequency variable display apparatus includes: a first subpixel disposed in a first pixel row and including a first driving transistor having a gate electrode connected to a first node and a source electrode connected to a second node, and a first light emitting element having an anode electrode connected to the second node; a second subpixel disposed in a second pixel row and including a second driving transistor having a gate electrode connected to a third node and a source electrode connected to a fourth node, and a second light emitting element having an anode electrode connected to the fourth node; a data line configured to transfer a first data voltage to the first node in a first gate-source setting period and transfer a second data voltage to the third node in a second gate-source setting period; and a reference voltage line configured to transfer a first initialization voltage to the second node in the first gate-source setting period and transfer a second initialization voltage to the fourth node in the second gate-source setting period, wherein the first initialization voltage differs from the second initialization voltage.

Embodiments of the present disclosure may realize the following effects.

One or more aspects of the present disclosure may increase a voltage level of an initialization voltage as a light emitting element is degraded. Accordingly, one or more aspects of the present disclosure may decrease a low grayscale recognition luminance deviation occurring in a rapid change condition of a frame frequency to improve VRR flicker and abnormal flashing, thereby enhancing display quality.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further features, advantages, and aspects are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIG. 1 is a block diagram illustrating a frequency variable display apparatus according to an example embodiment of the present disclosure;

FIG. 2 is a diagram illustrating a connection configuration of a pixel according to an example embodiment of the present disclosure;

FIG. 3 is a diagram illustrating an arrangement configuration of an organic light emitting diode (OLED) multi-stack and a color filter of a pixel according to an example embodiment of the present disclosure;

FIG. 4 is a diagram illustrating an example of an OLED multi-stack according to an example embodiment of the present disclosure;

FIG. 5 is a diagram illustrating a vertical active period and a vertical blank period configuring one frame time;

FIG. 6 is a diagram illustrating an example where a length of a vertical front porch included in a vertical blank period varies based on a level of a frame frequency;

FIG. 7 is a diagram illustrating an example where recognition luminance is changed based on a level of a frame frequency;

FIG. 8 is a diagram illustrating VRR flicker occurring in a rapid change condition of a frame frequency;

FIGS. 9 and 10 are diagrams illustrating an example where the visibility of VRR flicker is higher in a low gray level than a high gray level;

FIGS. 11 and 12 are diagrams illustrating a concept for decreasing VRR flicker;

FIG. 13 is a diagram illustrating another concept for decreasing VRR flicker;

FIG. 14 is a diagram illustrating an equivalent circuit of a subpixel according to an example embodiment of the present disclosure;

FIG. 15 is a diagram illustrating an example where an initialization voltage increases in proportion to a degradation in an OLED;

FIG. 16 is a diagram illustrating an example where a Coled charge time is reduced by the up-adjustment of an initialization voltage;

FIG. 17 is a diagram illustrating a Vgs variation of when an initialization voltage is applied at a default level;

FIG. 18 is a diagram illustrating a Vgs variation when an initialization voltage is applied at a voltage level which is higher than the default level;

FIG. 19 is a diagram illustrating an example where a peak luminance of a low grayscale region is reduced, when an initialization voltage VpreR is up-adjusted and/or a DTG coupling effect increases;

FIGS. 20A and 20B are diagrams illustrating a reason that an abnormal flashing phenomenon is severe when expressing a low gray level rather than a high gray level;

FIGS. 21 and 22 are diagrams illustrating an example where an abnormal flashing phenomenon occurs due to a capacitance deviation of capacitors configuring an OLED multi-stack;

FIG. 23 is a diagram illustrating an example where ΔVgs is reduced when an initialization voltage increases, and thus, an over-emission current level is lowered, and flashing is prevented;

FIG. 24 is a diagram illustrating the degree to which VRR flicker is improved as an initialization voltage increases and/or DTG coupling is reinforced;

FIG. 25 is a diagram illustrating an example where an initialization voltage is adjusted by units of pixel row;

FIGS. 26 and 27 are diagrams illustrating a driving example for supplying different initialization voltages to a first subpixel and a second subpixel disposed in an adjacent pixel row;

FIG. 28 is a driving waveform diagram for sensing a degradation in an OLED; and

FIGS. 29A, 29B, and 29C are diagrams illustrating a subpixel operation in a charge period, a discharge period, and a sensing period, respectively.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Reference is now made in detail to embodiments of the present disclosure, examples of which may be illustrated in the accompanying drawings. In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete to assist those skilled in the art to understand the inventive concepts without limiting the protected scope of the present disclosure.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

When the term “comprise,” “have,” “include,” “contain,” “constitute,” “made of,” “formed of,” “composed of,” or the like is used with respect to one or more elements (e.g., layers, films, components, electrodes, structures, transistors, sections, members, parts, regions, areas, portions, steps, operations, and/or the like), one or more other elements may be added unless a term such as “only” or the like is used. The terms used in the present disclosure are merely used in order to describe particular example embodiments, and are not intended to limit the scope of the present disclosure. Any references to singular may include plural, and vice versa, unless expressly stated otherwise. In one or more examples, unless expressly stated otherwise, an element may be one or more elements; and an element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

When a positional relationship between two elements (e.g., layers, films, components, electrodes, structures, transistors, sections, members, parts, regions, areas, portions, and/or the like) are described using any of the terms such as “on,” “on a top of,” “upon,” “on top of,” “over,” “under,” “above,” “upper,” “below,” “lower,” “beneath,” “near,” “close to,” “adjacent to,” “beside,” “next to,” “at or on a side of,” and/or the like indicating a position or location, one or more other elements may be located between the two elements unless a more limiting term, such as “immediate(ly),” “direct(ly),” or “close(ly),” is used. For example, when an element and another element are described using any of the foregoing terms, this description should be construed as including a case in which the elements contact each other directly as well as a case in which one or more additional elements are disposed or interposed therebetween. Furthermore, the spatially relative terms such as the foregoing terms as well as other terms such as “front,” “rear,” “back,” “left,” “right,” “top,” “bottom,” “upper,” “lower,” “downward,” “upward,” “up,” “down,” “column,” “row,” “vertical,” “horizontal,” “diagonal,” and the like refer to an arbitrary frame of reference. For example, these terms may be used for an example understanding of a relative relationship between elements, including any correlation as shown in the drawings. However, embodiments of the disclosure are not limited thereby or thereto. The spatially relative terms are to be understood as terms including different orientations of the elements in use or in operation in addition to the orientation depicted in the drawings or described herein. For example, where a lower element or an element positioned under another element is overturned, then the element may be termed as an upper element or an element positioned above another element. Thus, for example, the term “under” or “beneath” may encompass, in meaning, the term “above” or “over.” An example term “below” or the like, can include all directions, including directions of “below,” “above” and diagonal directions. Likewise, an example term “above,” “on” or the like can include all directions, including directions of “above,” “on,” “below” and diagonal directions.

In describing a temporal relationship, when the temporal order is described as, for example, “after,” “following,” “subsequent,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly),” is used.

It is understood that, although the terms “first,” “second,” “A,” “B,” “(a),” “(b),” and the like may be used herein to describe various elements (e.g., layers, films, components, electrodes, structures, transistors, sections, members, parts, regions, areas, portions, steps, operations, and/or the like), these elements should not be limited by these terms, for example, to any particular order, precedence, or number of elements. Further, these are not used to define the essence or basis of the elements. These terms are merely used to refer to one element separately from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

The expression that an element (e.g., layer, film, component, electrode, structure, transistor, section, member, part, region, area, portion, or the like) “is engaged” with another element may be understood, for example, as that the element may be either directly or indirectly engaged with the another element. The term “is engaged” or similar expressions may refer to a term such as “covers,” “surrounds,” “is in contact,” “overlaps,” “crosses,” “intersects,” “is connected,” “is coupled,” “is attached,” “is adhered,” “is combined,” “is linked,” “is provided,” “is disposed,” “interacts,” or the like. The engagement may involve one or more intervening elements disposed or interposed between the element and the another element, unless otherwise specified. Further, the element may be engaged at least partially or entirely (or completely) with the another element, unless otherwise specified. Further, the element may be included in at least one of two or more elements that are engaged with each other. Similarly, the another element may be included in at least one of two or more elements that are engaged with each other. When the element is engaged with the another element, at least a portion of the element may be engaged with at least a portion of the another element. The term “with another element” or similar expressions may be understood as “another element,” or “with, to, in, or on another element,” as appropriate by the context. Similarly, the term “with each other” may be understood as “each other,” or “with, to, or on each other,” as appropriate by the context.

The phrase “through” may be understood, for example, to be at least partially through or entirely through.

The terms such as a “line” or “direction” should not be interpreted only based on a geometrical relationship in which the respective lines or directions are parallel, perpendicular, diagonal, or slanted with respect to each other, and may be meant as lines or directions having wider directivities within the range within which the components of the present disclosure may operate functionally. For example, the terms “first direction,” “second direction,” “X-axis direction,” “Y-axis direction,” and the like should not be interpreted only based on a geometrical relationship in which the respective directions are parallel, perpendicular, diagonal, or slanted with respect to each other, and may be meant as directions having wider directivities within the range within which the components of the present disclosure may operate functionally.

The term “at least one” should be understood as including any and all combinations of one or more of the associated listed items. For example, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item. Further, at least one of a plurality of elements can represent (i) one element of the plurality of elements, (ii) some elements of the plurality of elements, or (iii) all elements of the plurality of elements. Further, “at least some,” “some,” “at least some portions,” “at least some parts,” “at least a portion,” “at least one or more portions,” “at least a part,” “at least one or more parts,” “at least some elements,” “one or more,” or the like of a plurality of elements can represent (i) one element of the plurality of elements, (ii) a portion (or a part) of the plurality of elements, (iii) one or more portions (or parts) of the plurality of elements, (iv) one or more elements of the plurality of elements, (v) multiple elements of the plurality of elements, or (vi) all of the plurality of elements. Moreover, “at least some,” “some,” “at least some portions,” “at least some parts,” “at least a portion,” “at least one or more portions,” “at least a part,” “at least one or more parts,” or the like of an element can represent (i) a portion (or a part) of the element, (ii) one or more portions (or parts) of the element, (iii) the element, or (iv) all portions of the element.

The expression of a first element, a second elements “and/or” a third element should be understood as any one of the first, second and third elements or as any or all combinations of the first, second and third elements. Similar interpretations apply to the use of “and/or” with two elements or with more than three elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

A phrase “substantially the same” or “nearly the same” may indicate a degree of being considered as being equivalent to each other taking into account minute differences due to errors in the manufacturing process.

Features of various embodiments of the present disclosure may be partially or entirely coupled to or combined with each other, may be technically associated with each other, and may be variously operated, linked or driven together in various ways. Embodiments of the present disclosure may be implemented or carried out independently of each other or may be implemented or carried out together in a co-dependent or related relationship. In one or more aspects, the components of each apparatus and device according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein. For example, the term “part” or “unit” may apply to, for example, a circuit, a component, an integrated circuit, a computational block of a circuit device, or a structure configured to perform a described function as should be understood by one of ordinary skill in the art.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example embodiments of the present disclosure are described in more detail with reference to the accompanying drawings. With respect to reference numerals to elements of each of the drawings, the same or similar elements may be illustrated in other drawings, and like reference numerals may refer to like or similar elements unless stated otherwise. The same or similar elements may be denoted by the same reference numerals even if they are depicted in different drawings. Repetitive descriptions of the same or similar elements may be omitted for brevity, and the descriptions provided for elements in one or more figures may also apply to elements in other figures that use the same or similar reference numerals unless stated otherwise. In addition, for the convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

In description of flow of a signal, for example, when a signal is provided (e.g., transferred or transmitted) from a node A to a node B, this may include a case where the signal is provided from the node A to the node B via one or more nodes unless a phrase such as “immediately provided,” “directly provided” or the like is used.

In one or more examples, a source electrode of a transistor may be referred to as a drain electrode of the transistor, and vice versa.

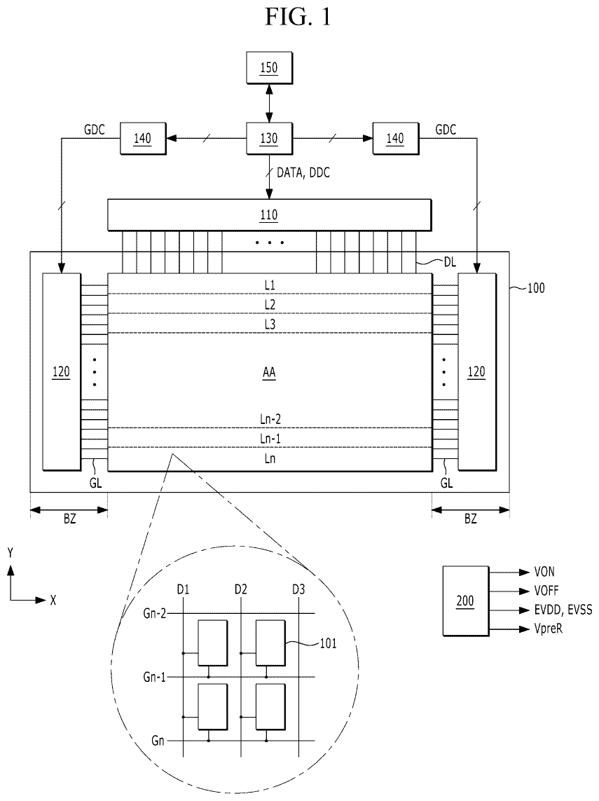

FIG. 1 is a block diagram illustrating a frequency variable display apparatus according to an example embodiment of the present disclosure.

Referring to FIG. 1, a display panel 100 may include a screen AA which displays an input image. The screen AA may include a pixel array which displays pixel data (hereinafter referred to as “image data”) DATA of an input image. The pixel array may include a plurality of data lines DL, a plurality of gate lines GL intersecting with the data lines DL, a plurality of reference voltage lines, and a plurality of pixels.

The pixels may be arranged on the screen AA in a matrix type defined by the data lines DL, the gate lines GL, and the reference voltage lines. The pixels may be arranged as various types, such as a stripe type and a diamond type as well as a matrix type, on the screen AA.

The pixel array may include a plurality of pixel columns and a plurality of pixel lines L1 to Ln intersecting with the pixel columns. Each of the pixel columns may include pixels which are arranged in a Y-axis direction. A pixel row may include pixels which are arranged in an X-axis direction. One vertical period may be one frame period needed for writing image data DATA of one frame in all pixels of the screen. One horizontal period may be a time obtained by dividing one frame period by the number of pixel lines L1 to Ln. One horizontal period may be a time needed for writing the image data DATA of one pixel row, sharing a gate line GL, in pixels of one pixel row.

Each of the pixels may include a red (R) subpixel 101, a green (G) subpixel 101, a blue (B) subpixel 101, and a white (W) subpixel 101 for implementing colors.

The frequency variable display apparatus according to one or more aspects of the present disclosure may be implemented as an electroluminescent display apparatus. In this case, a pixel circuit of the frequency variable display apparatus may include a light emitting element, a driving element, one or more switch elements, and a capacitor. The light emitting element may be implemented as an organic light emitting diode (OLED). A driving current Ioled which allows the light emitting element to emit light may be adjusted based on a gate-source voltage of the driving element. Each of the driving element and the switch element may be implemented as a transistor. A semiconductor layer of the transistor may include amorphous silicon or polysilicon. Semiconductor layers of at least some of transistors may include oxide. The pixel circuit may be connected to a data line DL and a gate line GL. In FIG. 1, “D1 to D3” illustrated in a circle may be data lines, and “Gn-2 to Gn” may be gate lines. Each of the subpixels 101 of FIG. 1 may include the same pixel circuit.

Touch sensors may be disposed on the display panel 100. The touch sensors may be arranged as an on-cell or add-on type on the screen AA of the display panel 100, or may be implemented as in-cell type touch sensors embedded in the pixel array. A touch input may be sensed through the touch sensors, or may be sensed through only pixels even without touch sensors.

A source driver 110 may convert the image data DATA, received from a timing controller 130, into gamma compensation voltages by using a digital-to-analog converter (DAC) to generate data voltages. The source driver 110 may supply the data voltages to the data lines DL. The data voltages may be supplied to the data lines DL and may be applied to gate electrodes of the driving elements through the switch elements of the subpixels 101. The source driver 110 may supply an initialization voltage VpreR, received from a power circuit 200, to reference voltage lines connected to the subpixels. The initialization voltage VpreR may be supplied to the reference voltage lines and may be applied to a source electrode of the driving element through a switch element of each subpixel 101.

The source driver 110 may be implemented with one or more source drive integrated circuits (ICs). The source drive IC may be connected to the timing controller 130 through an internal interface circuit. The internal interface circuit may be implemented as an embedded clock point to point interface (EPI). The source drive IC may further include a touch driver. The touch driver may generate a touch sensor driving signal and may convert an electric charge variation of a touch sensor into touch raw data. The touch driver may transfer the touch raw data to a host system (not shown) through a separate interface circuit. The separate interface circuit may be implemented as a serial peripheral interface (SPI).

A gate driver 120 may be provided in a bezel area BZ disposed outside the screen AA in the display panel 100. The bezel area BZ may not display an image. The gate driver 120 may sequentially supply a gate signal, synchronized with data voltages, to the gate lines GL according to control by the timing controller 130. The gate signal may simultaneously activate pixels of the same pixel row into which a data voltage is charged. The gate driver 120 may output the gate signal by using one or more shift registers and may shift the gate signal. The gate signal may be referred to as a scan signal. The scan signal may include a gate on voltage VON and a gate off voltage VOFF, which are received from the power circuit 200.

The timing controller 130 may receive video data DATA and a timing signal, synchronized with the video data DATA, from the host system (not shown). The timing signal may include a vertical synchronization signal Vsync, a horizontal synchronization signal Hsync, a clock signal DCLK, and a data enable signal DE. The vertical synchronization signal Vsync may define a vertical period (i.e., one frame). The horizontal synchronization signal Hsync may define a horizontal period. The data enable signal DE may define a time (i.e., a vertical active period) where data voltages are input to subpixels in a vertical period. The other time, except the vertical active period, of the vertical period may be a vertical blank period. The data enable signal DE may swing in the vertical active period and may not swing in the vertical blank period.

The timing controller 130 may generate a source timing control signal DDC for controlling an operation timing of the source driver 110 and a gate timing control signal GDC for controlling an operation timing of the gate driver 120, based on the timing signal Vsync, Hsync, and DE received from the host system.

The host system may be one of a television (TV), a set-top box, a navigation system, a personal computer (PC), a home theater, an automotive display system, a mobile device, and a wearable device. In the mobile device and the wearable device, the source driver 110, the timing controller 130, and a level shifter 140 may be integrated into one drive IC.

The level shifter 140 may shift a logic voltage level of the gate timing control signal GDC, output from the timing controller 130, to the gate on voltage VON or the gate off voltage VOFF to supply to the gate driver 120. A low logic voltage of the gate timing control signal GDC may be down-shifted to the gate off voltage VOFF, and a high logic voltage of the gate timing control signal GDC may be up-shifted to the gate on voltage VON.

The power circuit 200 may generate various source voltages needed for panel driving. The power circuit 200 may generate the gate on voltage VON and the gate off voltage VOFF needed for generating of the scan signal, generate a high-level source voltage EVDD and a low-level source voltage EVSS which are to be supplied to each subpixel 101, and generate the initialization voltage VpreR which is to be supplied to a reference voltage line.

The timing controller 130, the source driver 110, the gate driver 120, and the power circuit 200 may be elements configuring a flicker compensation circuit according to an example embodiment of the present disclosure. The flicker compensation circuit may increase the initialization voltage VpreR applied to subpixels in proportion to a degradation in a light emitting element OLED, and thus, may reduce a recognition luminance deviation between frames occurring in a rapid change condition of a frame frequency. Particularly, when a data voltage is low based on a low gray level, an internal capacitor (hereinafter referred to as Coled) charge time of the light emitting element OLED may increase, and due to this, VRR flicker may occur. On the other hand, the flicker compensation circuit according to an example embodiment of the present disclosure may increase a voltage level of the initialization voltage VpreR, and thus, may shorten the charge time of Coled and may reduce VRR flicker.

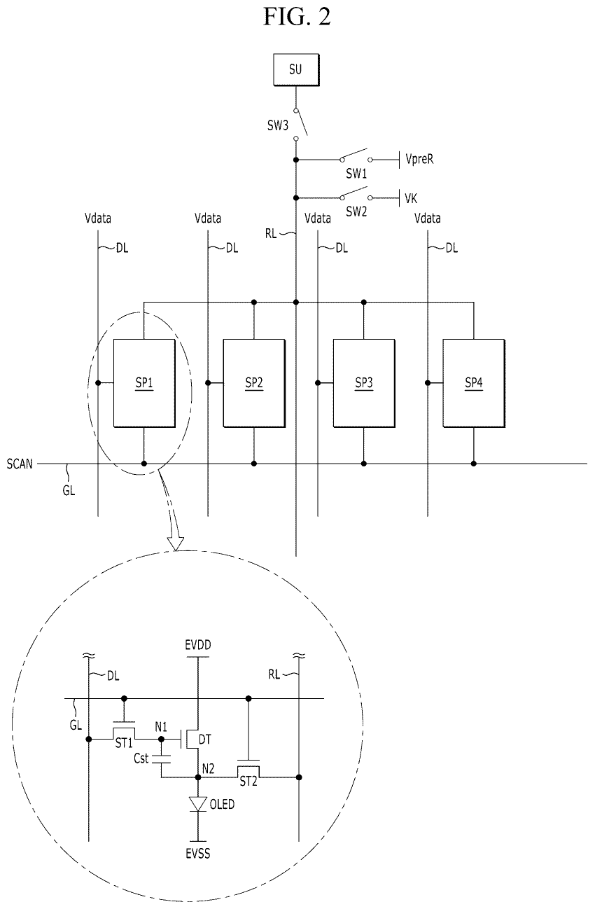

FIG. 2 is a diagram illustrating a connection configuration of a pixel according to an example embodiment of the present disclosure.

Referring to FIG. 2, the pixel may include four subpixels SP1 to SP4 which share a reference voltage line RL. The four subpixels SP1 to SP4 may be R, G, B, and W subpixels for configuring the same pixel. Each of the subpixels SP1 to SP4 may include, for example, a light emitting element OLED, a driving transistor DT, first and second switch transistors ST1 and ST2, and a storage capacitor Cst.

The light emitting element OLED may emit light with a driving current Ioled supplied from the driving transistor DT to implement luminance. An anode electrode of the light emitting element OLED may be connected to a second node N2, and a cathode electrode thereof may be connected to an input terminal of a low-level source voltage EVSS.

The driving transistor DT may generate the driving current Ioled based on a gate-source voltage thereof to supply the driving current Ioled to the light emitting element OLED. A gate electrode of the driving transistor DT may be connected to a first node N1, a drain electrode thereof may be connected to an input terminal of a high-level source voltage EVDD, and a source electrode thereof may be connected to the second node N2.

A gate electrode of the first switch transistor ST1 may be connected to a gate line GL. A first electrode of the first switch transistor ST1 may be connected to a data line DL, and a second electrode thereof may be connected to the first node N1.

A gate electrode of the second switch transistor ST2 may be connected to the gate line GL. A first electrode of the second switch transistor ST2 may be connected to a reference voltage line RL, and a second electrode thereof may be connected to the second node N2.

One electrode of the storage capacitor Cst may be connected to the first node N1, and the other electrode thereof may be connected to the second node N2.

The first and second switch transistors ST1 and ST2 may be turned on based on a scan signal SCAN of the gate on voltage VON in a vertical active period, and thus, may connect the gate electrode of the driving transistor DT to the data line DL and may connect the source electrode of the driving transistor DT to the reference voltage line RL. Therefore, a data programming operation corresponding to image data may be performed. The data programming operation may be referred to as a gate-source voltage Vgs setting operation on the driving transistor DT. The gate-source voltage Vgs may be a difference voltage “Vdata−VpreR” between a data voltage Vdata and an initialization voltage VpreR. When the data programming operation is completed in the vertical active period, the first and second switch transistors ST1 and ST2 may be turned off based on a scan signal SCAN of the gate off voltage VOFF.

A first switch SW1, a second switch SW2, and a third switch SW3 may be further connected to the reference voltage line RL. The first switch SW1 may connect an input terminal of the initialization voltage VpreR to the reference voltage line RL. The second switch SW2 may connect the reference voltage line RL to a tracking voltage VK for sensing OLED degradation. The third switch SW3 may connect the reference voltage line RL to a sensing circuit SU for sensing OLED degradation. Because the second switch SW2 and the third switch SW3 are for sensing OLED degradation, the elements SW2, SW3, and SU may be omitted in a model which predicts OLED degradation, based on data counting.

The first switch SW1 may be connected to the reference voltage line RL in the display driving. The second switch SW2 and the third switch SW3 may be connected to the reference voltage line RL in a power off sequence or a power on sequence where the display driving is not performed. While the second switch SW2 is connected to the reference voltage line RL, electrical connections between the first and third switches SW1 and SW3 and the reference voltage line RL may be disconnected. On the other hand, while the third switch SW3 is connected to the reference voltage line RL, electrical connections between the first and second switches SW1 and SW2 and the reference voltage line RL may be disconnected. An OLED sensing operation of the sensing circuit SU may be performed while the third switch SW3 is connected to the reference voltage line RL.

The first switch SW1, the second switch SW2, the third switch SW3, and the sensing circuit SU may be included in the source driver 110.

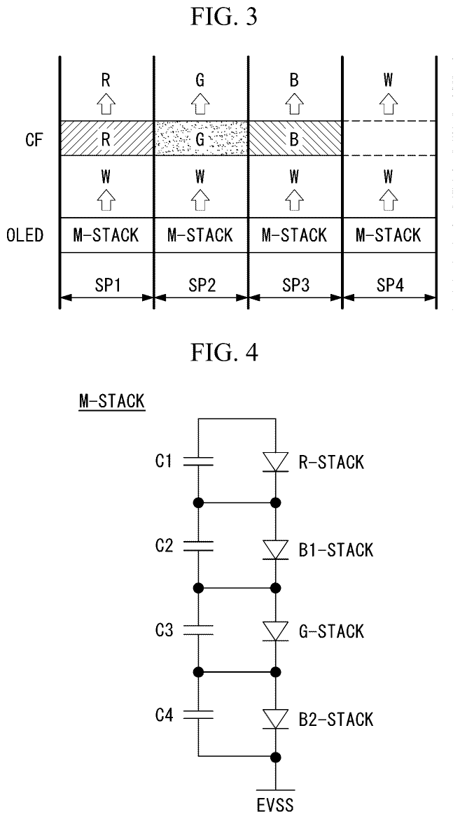

FIG. 3 is a diagram illustrating an arrangement configuration of an OLED multi-stack and a color filter of a pixel according to an example embodiment of the present disclosure. FIG. 4 is a diagram illustrating an example of an OLED multi-stack according to an example embodiment of the present disclosure.

Referring to FIGS. 3 and 4, a light emitting element OLED of each of R, G, B, and W subpixels SP1 to SP4 may be implemented in a multi-stack structure M-STACK. As an example of the multi-stack structure M-STACK, there may be a 4-stack structure. The 4-stack structure may be configured with an R stack, a B1 stack, a G stack, and a B2 stack, which are sequentially and serially connected to one another. An internal capacitor C1 may be formed at both anode-cathode ends of the R stack, an internal capacitor C2 may be formed at both anode-cathode ends of the B1 stack, an internal capacitor C3 may be formed at both anode-cathode ends of the G stack, and an internal capacitor C4 may be formed at both anode-cathode ends of the B2 stack.

The light emitting element OLED of each of the R, G, B, and W subpixels SP1 to SP4 may include the 4-stack structure to generate white (W) light. The white (W) light may be converted into red (R) light, green (G) light, or blue (B) light in a color filter array disposed on a multi-stack array.

In the R subpixel SP1, the white (W) light generated by the light emitting element OLED may pass through an R color filter CF-R and may thus be converted into red (R) light, and then, may be output to the outside. In the G subpixel SP2, the white (W) light generated by the light emitting element OLED may pass through a G color filter CF-G and may thus be converted into green (G) light, and then, may be output to the outside. In the B subpixel SP3, the white (W) light generated by the light emitting element OLED may pass through a B color filter CF-B and may thus be converted into blue (B) light, and then, may be output to the outside. Furthermore, in the W subpixel SP4, the white (W) light generated by the light emitting element OLED may bypass a color filter CF and may be output to the outside.

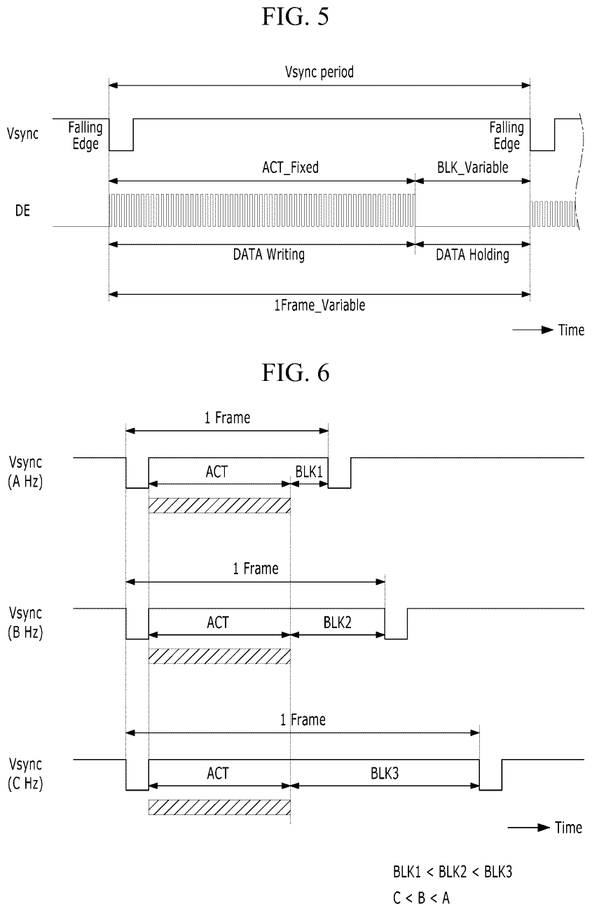

FIG. 5 is a diagram illustrating a vertical active period and a vertical blank period configuring one frame time. FIG. 6 is a diagram illustrating an example where a length of a vertical front porch included in a vertical blank period varies based on a level of a frame frequency.

Referring to FIG. 5, one frame time (vertical period) may be defined by a vertical synchronization signal Vsync. The one frame time (vertical period) may be defined as a time interval between adjacent falling edges (or rising edges) of the vertical synchronization signal Vsync.

A vertical active period ACT and a vertical blank period BLK in the one frame time (vertical period) may be defined by a data enable signal DE. The vertical active period ACT may be a period where the data enable signal DE swings, and the vertical blank period BLK may be a period where the data enable signal DE does not swing.

The frequency variable display apparatus according to one or more aspects of the present disclosure may operate in a VRR mode where a length of one frame varies. In the VRR mode, as in FIG. 6, a frame frequency may be changed to A, B, and C Hz. When a frame frequency is changed, a length of one frame time may vary based thereon. In the VRR mode, a length of the vertical active period ACT may be fixed to a predetermined certain value, and a length of the vertical blank period BLK may vary based on a frame frequency. A length of the vertical blank period may be BLK1, based on a frame frequency of A Hz, a length of the vertical blank period may be BLK2, based on a frame frequency of B Hz, and a length of the vertical blank period may be BLK3, based on a frame frequency of C Hz. Here, when A>B>C, BLK1<BLK2<BLK3.

During the vertical active period ACT of a fixed length, a gate-source voltage setting (i.e., data programming) operation may be performed in pixels, based on a data voltage corresponding to image data DATA. During the vertical blank period BLK of a variable length, a gate-source voltage set in pixels may be held.

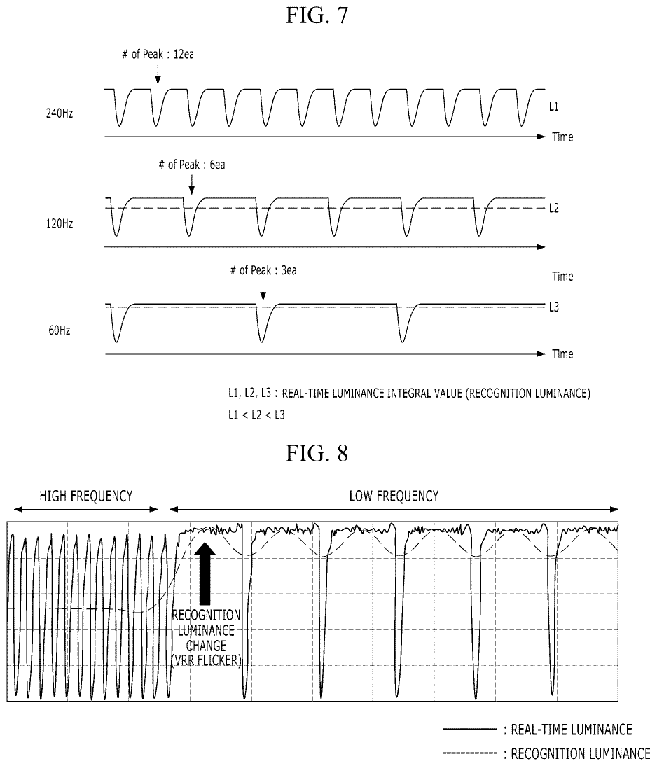

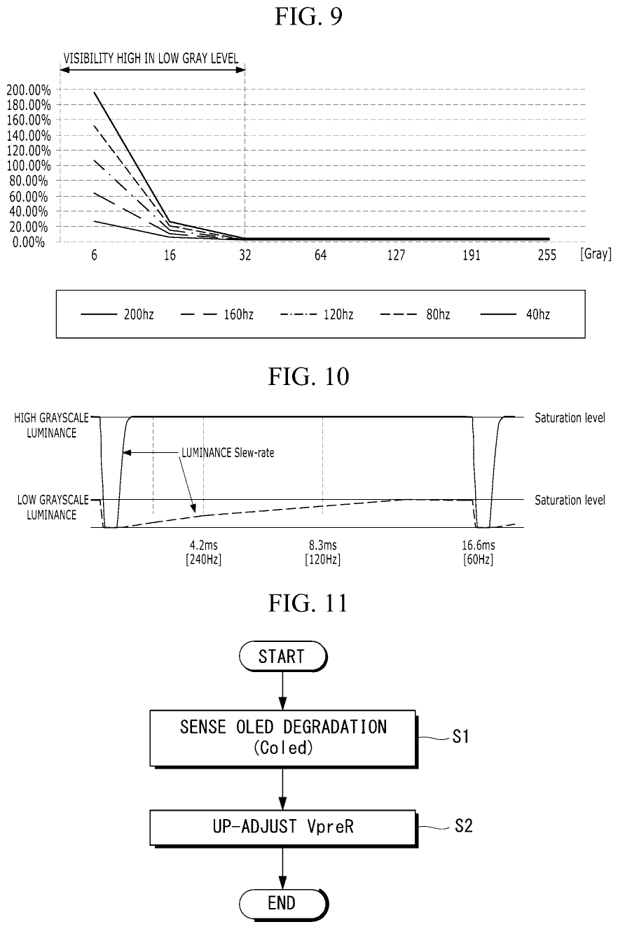

FIG. 7 is a diagram illustrating an example where recognition luminance is changed based on a level of a frame frequency. FIG. 8 is a diagram illustrating VRR flicker occurring in a rapid change condition of a frame frequency. FIGS. 9 and 10 are diagrams illustrating an example where the visibility of VRR flicker is higher in a low gray level than a high gray level.

Peak low luminance points of FIGS. 7 and 8 may be points at which data programming operations are performed. An emission operation of a light emitting element OLED may stop while the data programming operation is being performed, and the emission operation of the light emitting element OLED may be performed after the data programming operation is performed.

The data programming operation and the emission operation may be successively performed in one frame. The number of data programming operations may increase as the number of frame arrangements in a predetermined time increases, namely, a frame frequency increases, and thus, recognition luminance may be lowered. For example, the number of data programming operations in a predetermined time in a frame frequency of 240 Hz may be twelve, the number of data programming operations in a predetermined time in a frame frequency of 120 Hz may be six, and the number of data programming operations in a predetermined time in a frame frequency of 60 Hz may be three. As a result, a real-time luminance integral value (i.e., recognition luminance) of a frame frequency of 240 Hz may be L1, a real-time luminance integral value (i.e., recognition luminance) of a frame frequency of 120 Hz may be L2 which is higher than L1, and a real-time luminance integral value (i.e., recognition luminance) of a frame frequency of 60 Hz may be L3 which is higher than L2.

As described above, when it is assumed that a gray level of a display image is constant, recognition luminance may be relatively higher in a case, where a frame frequency is a low frequency, than a case where the frame frequency is a high frequency. Accordingly, VRR flicker caused by a change in recognition luminance may occur when the frame frequency is changed from a high frequency to a low frequency.

VRR flicker, as in FIGS. 9 and 10, may be perceived relatively higher in a low grayscale period than a high grayscale period. In a case where a time taken until reaching a target luminance saturation level immediately after data programming is defined as a luminance slew rate, a luminance slew rate of a high grayscale image may be relatively greater than a luminance slew rate of a low grayscale image. Accordingly, VRR flicker caused by a change in frequency may not be largely issued in a high grayscale image, but may be clearly recognized when displaying a low grayscale image.

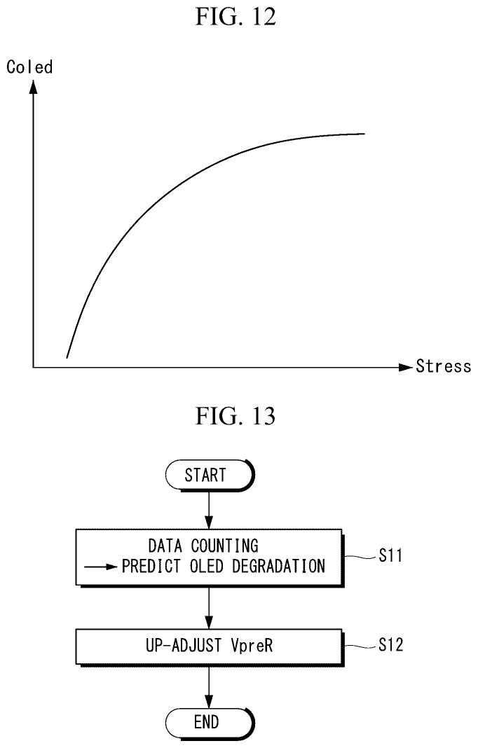

FIGS. 11 and 12 are diagrams illustrating a concept for decreasing VRR flicker.

Referring to FIGS. 11 and 12, the flicker compensation circuit according to an example embodiment of the present disclosure may sense a degradation in the light emitting element OLED in step S1. As the degree of degradation of the light emitting element OLED increases, a capacitance component and a resistance component of the light emitting element OLED may increase. The flicker compensation circuit may sense an OLED threshold voltage charged in the capacitor Coled of the light emitting element OLED to determine a degradation in the light emitting element OLED. In FIG. 12, the vertical axis “Coled” denotes an OLED threshold voltage charged in the capacitor Coled of the light emitting element OLED, and the horizontal axis “Stress” denotes a degree of degradation in the light emitting element OLED.

The flicker compensation circuit may sense all subpixels of a screen, or may sense only some subpixels. The flicker compensation circuit may determine a mean value or the most frequent value of sensing values as a representative sensing value and may up-adjust a voltage level of the initialization voltage VpreR, based on the representative sensing value in step S2.

The up-adjusted initialization voltage VpreR may be supplied to all subpixels of the screen, for the data programming operation.

As the degree of degradation in the light emitting element OLED increases, the flicker compensation circuit may increase a voltage level of the initialization voltage VpreR. For example, the flicker compensation circuit may adjust the initialization voltage VpreR to a first voltage level, based on a degradation sensing value of a first value, and may adjust the initialization voltage VpreR to a second voltage level which is higher than the first voltage level, based on a degradation sensing value of a second value greater than the first voltage. When the initialization voltage VpreR is up-adjusted based on a degradation in the light emitting element OLED, VRR flicker may decrease, and an abnormal flashing phenomenon may be improved.

FIG. 13 is a diagram illustrating another concept for decreasing VRR flicker.

Referring to FIG. 13, the flicker compensation circuit according to an example embodiment of the present disclosure may predict a degradation in the light emitting element OLED, based on an accumulated emission history of the light emitting element OLED in step S11. The accumulated emission history of the light emitting element OLED may include an image display time and an image display gray level. The accumulated emission history of the light emitting element OLED may be checked based on data counting accumulation technology. The data counting accumulation technology may be degradation prediction modeling technology which converts input image data into a stress value to accumulate the stress value in a memory (150 of FIG. 1). As a driving time of a high grayscale image increases, the stress value accumulated in the memory (150 of FIG. 1) may increase.

The flicker compensation circuit may predict a degradation in the light emitting element OLED, based on data counting on at least some subpixels of a screen. The flicker compensation circuit may up-adjust a voltage level of the initialization voltage VpreR, based on a degradation prediction value of the light emitting element OLED in step S12.

The up-adjusted initialization voltage VpreR may be supplied to all subpixels of the screen, for a data programming operation.

As the degree of degradation in the light emitting element OLED increases, the flicker compensation circuit may increase a voltage level of the initialization voltage VpreR. For example, the flicker compensation circuit may adjust the initialization voltage VpreR to a first voltage level, based on a degradation prediction value of a first value, and may adjust the initialization voltage VpreR to a second voltage level which is higher than the first voltage level, based on a degradation prediction value of a second value greater than the first voltage. When the initialization voltage VpreR is up-adjusted based on a degradation in the light emitting element OLED, VRR flicker may decrease, and an abnormal flashing phenomenon may be improved.

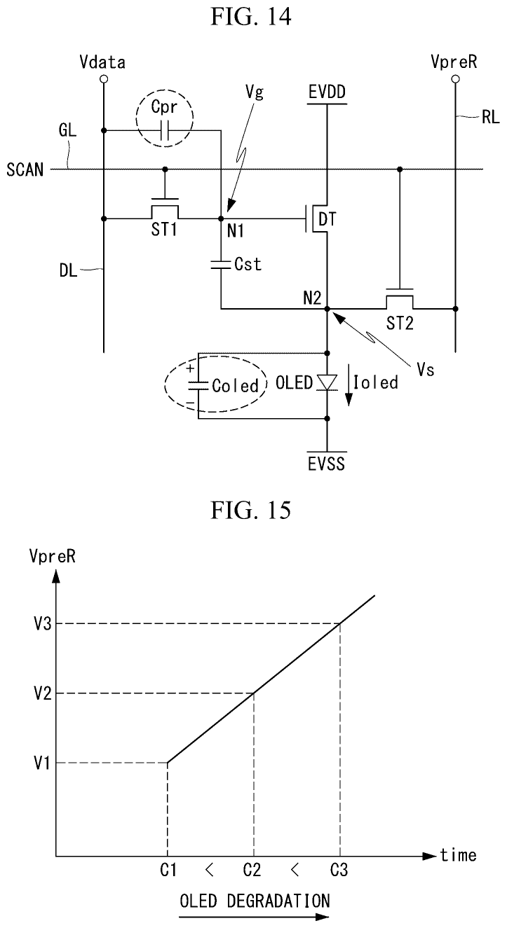

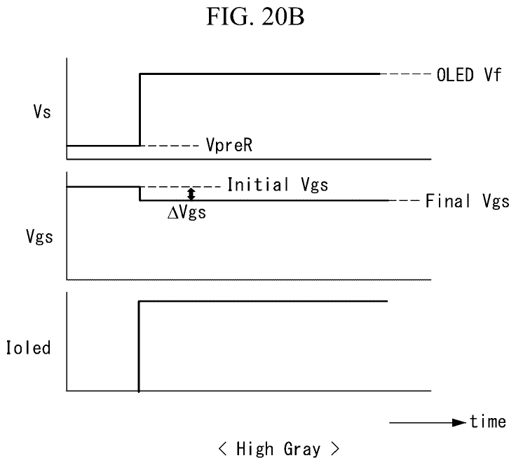

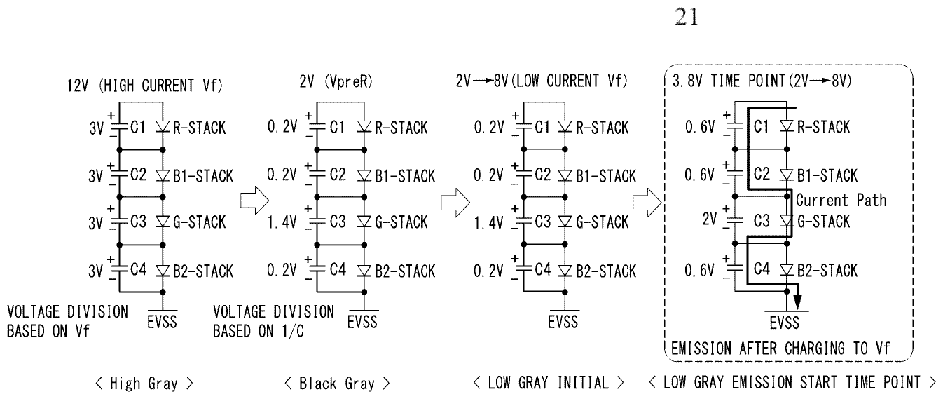

Hereinafter, the principle that VRR flicker is reduced by the up-adjustment of the initialization voltage VpreR will be described with reference to FIGS. 14 to 19. Also, the principle that an abnormal flashing phenomenon is improved by the up-adjustment of the initialization voltage VpreR will be described with reference to FIGS. 20A to 23.

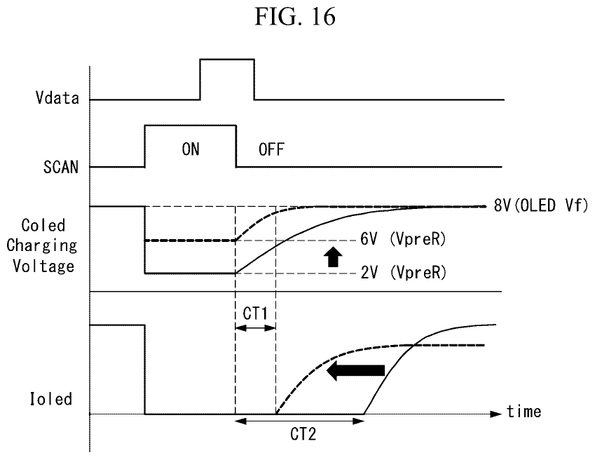

FIG. 14 is a diagram illustrating an equivalent circuit of a subpixel according to an example embodiment of the present disclosure. FIG. 15 is a diagram illustrating an example where an initialization voltage increases in proportion to a degradation in an OLED. FIG. 16 is a diagram illustrating an example where an initialization voltage is up-adjusted as a capacitance of a capacitor Coled increases.

Referring to FIGS. 14 and 15, as a light emitting element OLED is degraded, a capacitance of a Coled may increase from C1 to C2 and C3. When the capacitance of the Coled increases, an OLED threshold voltage charged in the Coled may increase. Accordingly, when a voltage of the Coled is sensed, the degree of degradation in the light emitting element OLED may be confirmed.

An initialization voltage VpreR may be up-adjusted from V1 to V2 and V3 in proportion to a degradation in the light emitting element OLED. When the initialization voltage VpreR increases, a charge time of the Coled (a non-emission time) may be shortened, or a DTG coupling effect may increase, thereby reducing VRR flicker.

The DTG coupling effect may denote that a gate electric potential of a driving transistor DT varies based on a voltage variation of a data line DL. The DTG coupling effect may be implemented through a coupling capacitor Cpr where one electrode thereof is connected to a first node N1, and the other electrode thereof is connected to the data line DL. A DTG coupling ratio may be determined to be “Cpr capacitance/(Cst capacitance+Cpr capacitance)”. As the Cpr capacitance increases, or the Cst capacitance decreases, a coupling ratio may increase, and thus, the DTG coupling effect may increase.

For an appropriate DTG coupling effect, a capacitance of the coupling capacitor Cpr may be set to 0.1% to 0.5% of a capacitance of a storage capacitor Cst.

When the capacitance of the coupling capacitor Cpr is less than 0.1% of the capacitance of the storage capacitor Cst, there may be a problem where a desired coupling effect is not sufficient, and when the capacitance of the coupling capacitor Cpr is greater than 0.5% of the capacitance of the storage capacitor Cst, there may be a problem where a coupling effect increases excessively, and due to this, a luminance in a vertical blank period is largely changed. In one or more aspects, to obtain an appropriate coupling effect, it may be preferable that the capacitance of the coupling capacitor Cpr is set to 0.1% to 0.5% of the capacitance of the storage capacitor Cst.

FIG. 16 is a diagram illustrating an example where a Coled charge time is reduced by the up-adjustment of an initialization voltage.

Referring to FIG. 16, when an initialization voltage VpreR is up-adjusted from 2 V to 6 V, based on a degradation in a light emitting element OLED, the Coled charge time may be shortened from CT2 to CT1. The Coled charge time being shortened may denote that a turn-on time of a light emitting element OLED is advanced, and thus, an emission time increases. VRR flicker issued in a low gray level may be associated with a luminance slew rate. When the initialization voltage VpreR is up-adjusted from 2 V to 6 V, an emission time of the light emitting element OLED in one frame may increase, and thus, a time for reaching target luminance may be shortened in proportion thereto. That is, a luminance slew rate for reaching the target luminance may increase, and thus, VRR flicker issued in a low gray level may be improved.

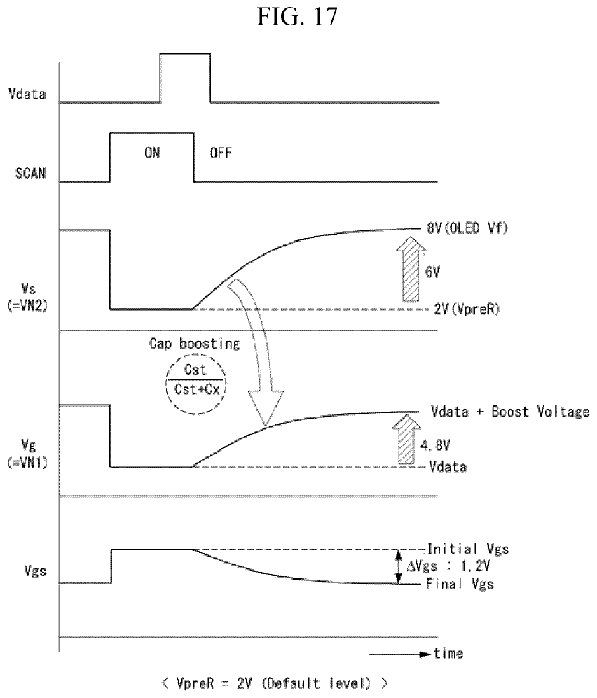

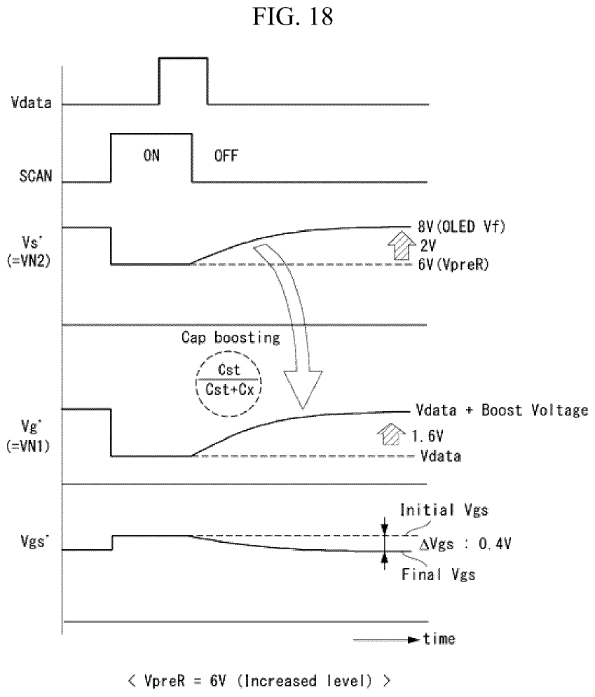

FIG. 17 is a diagram illustrating a Vgs variation of when an initialization voltage is applied at a default level. FIG. 18 is a diagram illustrating a Vgs variation when an initialization voltage is applied at a voltage level which is higher than the default level.

Referring to FIGS. 14 and 17, when the driving transistor DT operates as the initialization voltage VpreR is applied to the second node N2 as 2 V of a default level and the data voltage Vdata is applied to the first node N1, a source voltage Vs may increase from 2 V to 8 V which is an OLED turn-on voltage Vf, based on a current flowing through the driving transistor DT. At this time, a gate voltage Vg may also increase from a data voltage Vdata to “Vdata+boosting voltage” through cap-boosting based on the storage capacitor Cst. A cap-boosting ratio may be defined as “Cst capacitance/(Cst capacitance+Cx parasitic capacitance)”. In an example, Cx parasitic capacitance may be a parasitic capacitance between the gate and source of the driving transistor DT. When the cap-boosting ratio is 80%, a boosting voltage may be 6V*0.8, namely, may be 4.8 V. That is, the gate voltage Vg may increase to “Vdata+4.8V”. As a result, a difference voltage ΔVgs between initial Vgs and final Vgs may be 1.2 V. The initial Vgs may be a gate-source voltage of the driving transistor DT based on data programming. The final Vgs may be a gate-source voltage of the driving transistor DT at an emission time of the light emitting element OLED. As described above, when ΔVgs is high, a drain-source current deviation ΔIds of the driving transistor DT may increase. When the drain-source current deviation ΔIds of the driving transistor DT increases, a recognition luminance change may increase, and due to this, VRR flicker may be easily recognized in a low gray level.

Referring to FIGS. 14 and 18, when the driving transistor DT operates as the initialization voltage VpreR is applied to the second node N2 as up-adjusted 6 V and the data voltage Vdata is applied to the first node N1, the source voltage Vs may increase from 6 V to 8 V which is the OLED turn-on voltage Vf, based on a current flowing through the driving transistor DT. At this time, the gate voltage Vg may also increase from the data voltage Vdata to “Vdata +boosting voltage” through cap-boosting based on the storage capacitor Cst. When the cap-boosting ratio is 80%, a boosting voltage may be 2V*0.8, namely, may be 1.6 V. That is, the gate voltage Vg may increase to “Vdata+1.6V”. As a result, the difference voltage ΔVgs between the initial Vgs and the final Vgs may be 0.4 V. As described above, when ΔVgs deceases through the up-adjustment of the initialization voltage VpreR, the drain-source current deviation ΔIds of the driving transistor DT may decrease. When the drain-source current deviation ΔIds of the driving transistor DT decreases, a recognition luminance change may decrease, and thus, VRR flicker may be prevented in a low gray level.

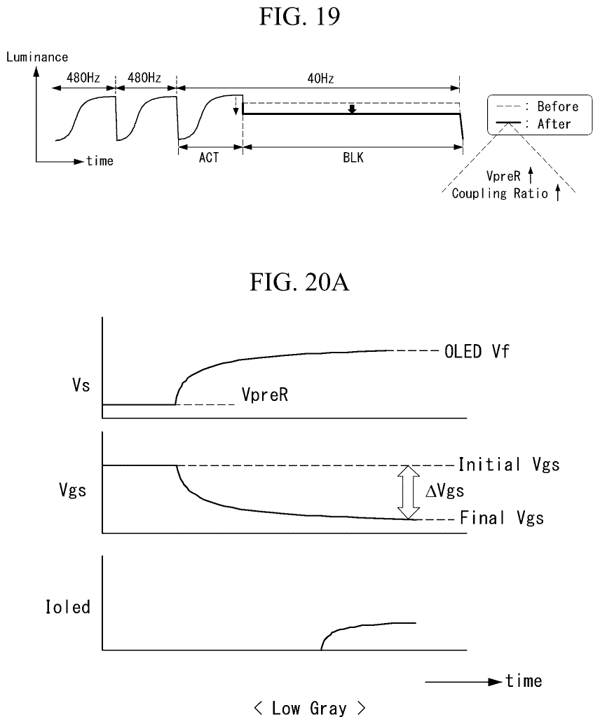

FIG. 19 is a diagram illustrating an example where a peak luminance of a low grayscale region is reduced, when an initialization voltage VpreR is up-adjusted and/or a DTG coupling effect increases.

Referring to FIG. 19, in a case where the initialization voltage VpreR is up-adjusted and/or a DTG coupling ratio increases, even when a frame frequency is rapidly changed from 480 Hz to 40 Hz, a peak luminance of a low grayscale area may decrease, and thus, VRR flicker may be improved.

FIGS. 20A and 20B are diagrams illustrating a reason that an abnormal flashing phenomenon is severe when expressing a low gray level rather than a high gray level.

Referring to FIGS. 20A and 20B, because cap-boosting transfer loss is greater in a case which implements a low gray level than a case which implements a high gray level, the difference voltage ΔVgs between the initial Vgs and the final Vgs may be relatively large. When ΔVgs is large, an abnormal flashing phenomenon may occur in a low gray level.

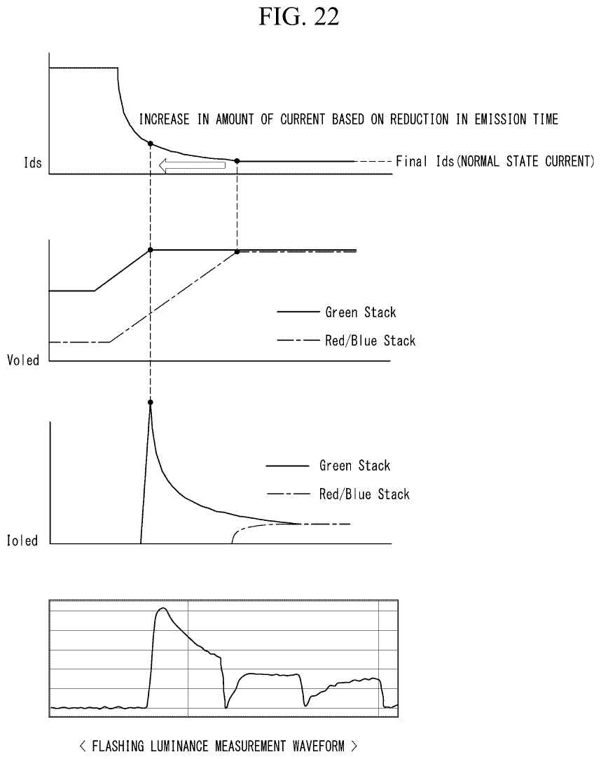

FIGS. 21 and 22 are diagrams illustrating an example where an abnormal flashing phenomenon occurs due to a capacitance deviation of capacitors configuring an OLED multi-stack.

Referring to FIG. 21, a capacitance of a G stack may be 75% greater than capacitances of a R stack, a B1 stack, and a B2 stack.

When implementing a high gray level, the R stack, the B1 stack, the G stack, and the B2 stack may divide a high current OLED turn-on voltage Vf of 12 V by units of 3 V.

Subsequently, when implementing a black gray level, the R stack, the B1 stack, the G stack, and the B2 stack may divide a voltage, based on 1/capacitance. The R stack, the B1 stack, the G stack, and the B2 stack may respectively divide an initialization voltage VpreR of 2 V into 0.2 V, 0.2 V, 1.4 V, and 0.2 V.

Subsequently, at an initial time for low gray level implementation, the R stack, the B1 stack, the G stack, and the B2 stack may respectively divide 2 V into 0.2 V, 0.2 V, 1.4 V, and 0.2 V.

Subsequently, at an emission start time for low gray level implementation, the R stack, the B1 stack, the G stack, and the B2 stack may respectively divide 3.8 V into 0.6 V, 0.6 V, 2 V, and 0.6 V. At this time, an emission time of the G stack may be earlier than emission times of the R stack, the B1 stack, and the B2 stack. As the emission time of the G stack is reduced, the amount of current may increase, and due to this, abnormal transition emission (i.e., flashing) may occur.

As described above, an abnormal flashing phenomenon may be caused by a capacitance unbalance of each stack.

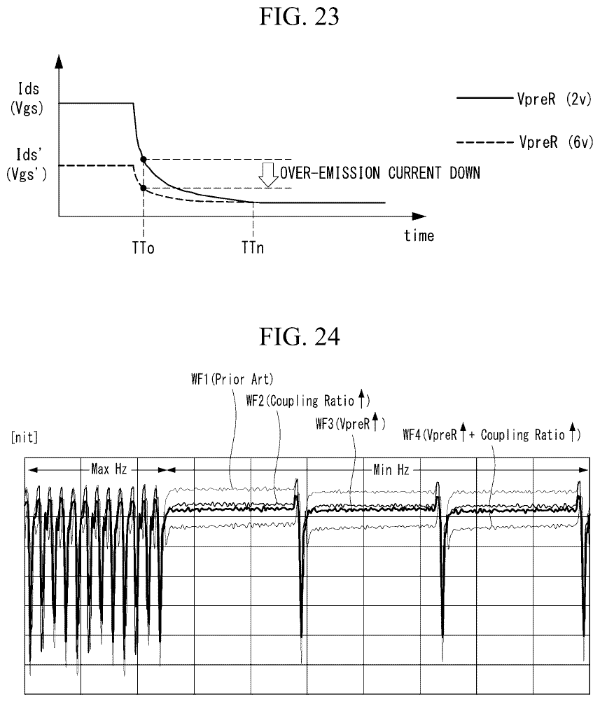

FIG. 23 is a diagram illustrating an example where ΔVgs is reduced when an initialization voltage increases, and thus, an over-emission current level is lowered, and flashing is prevented.

Referring to FIG. 23, when an initialization voltage VpreR is up-adjusted from 2 V to 6 V, an over-emission current level at an early emission time TTo which is earlier than a normal emission time TTn may be lowered, and thus, despite early emission, abnormal flashing may be effectively prevented.

FIG. 24 is a diagram illustrating the degree to which VRR flicker is improved as an initialization voltage increases and/or DTG coupling is reinforced.

Referring to FIG. 24, a waveform WF1 represents a luminance change of the prior art, a waveform WF2 represents an improved luminance change when a DTG coupling ratio increases, a waveform WF3 represents an improved luminance change when an initialization voltage VpreR increases, and a waveform WF4 represents an improved luminance change when the DTG coupling ratio increases and the initialization voltage VpreR increases by 2 V.

In terms of a VRR flicker improvement effect, the waveform WF4 may be the best, the waveform WF3 may be second good, and the waveform WF2 may be third good.

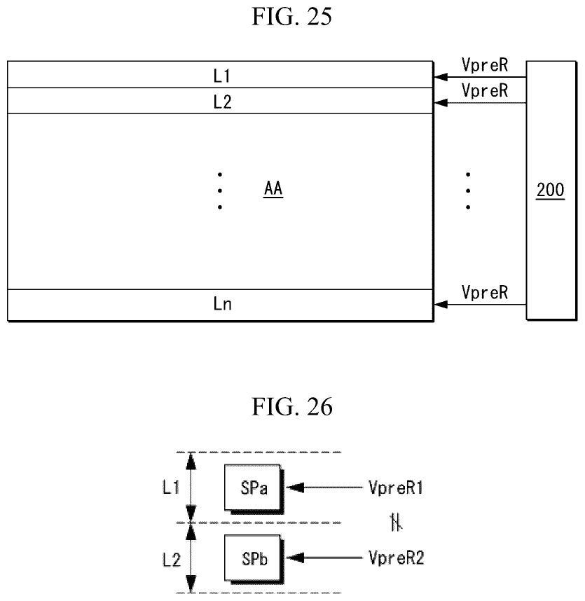

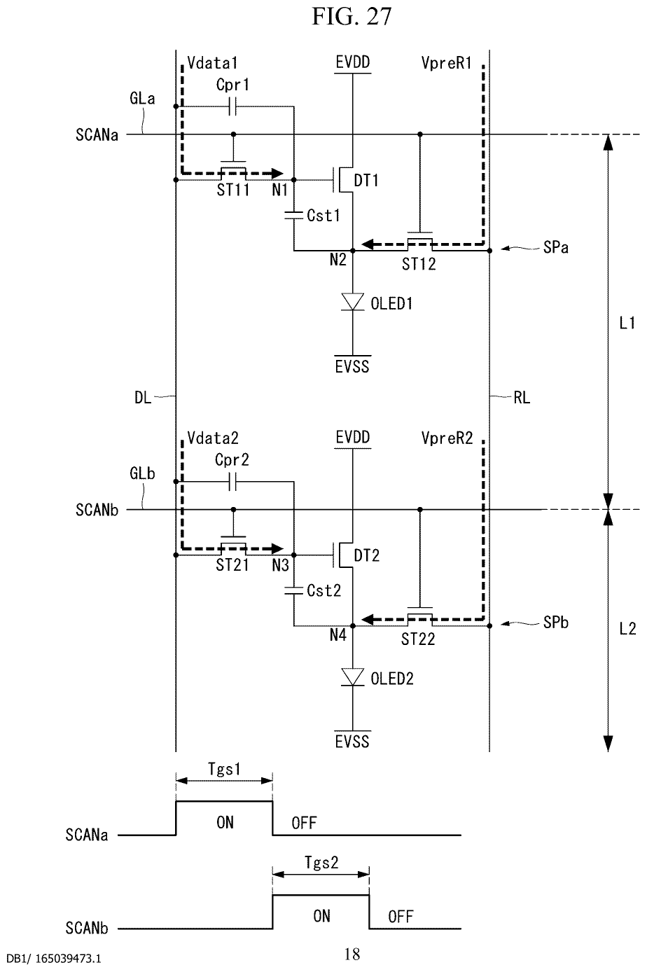

FIG. 25 is a diagram illustrating an example where an initialization voltage is adjusted by units of pixel row. FIGS. 26 and 27 are diagrams illustrating a driving example for supplying different initialization voltages to a first subpixel and a second subpixel disposed in an adjacent pixel row.

Referring to FIG. 25, an initialization voltage VpreR may be independently adjusted by units of pixel rows L1 to Ln. To this end, a degradation in a light emitting element OLED may be sensed by units of pixel rows L1 to Ln, or may be predicted based on data counting.

Because the initialization voltage VpreR is independently adjusted by units of pixel rows L1 to Ln, as in FIGS. 26 and 27, different initialization voltages VpreR1 and VpreR2 may be supplied to a first subpixel SPa and a second subpixel SPb disposed in adjacent pixel rows L1 and L2, respectively.

In detail, as in FIG. 27, the first subpixel SPa may include a first driving transistor DT1 including a gate electrode connected to a first node N1 and a source electrode connected to a second node N2, and a first light emitting element OLED1 including an anode electrode connected to the second node N2 and may be disposed in a first pixel row L1. The first subpixel SPa may further include a switch transistor ST11 which is connected to a data line DL and the first node N1 and is turned on or off based on a first scan signal SCANa, a switch transistor ST12 which is connected to a reference voltage line RL and the second node N2 and is turned on or off based on the first scan signal SCANa, a first coupling capacitor Cpr1 which is connected to the data line DL and the first node N1, and a first storage capacitor Cst1 which is connected to the first node N1 and the second node N2.

The second subpixel SPb may include a second driving transistor DT2 including a gate electrode connected to a third node N3 and a source electrode connected to a fourth node N4 and, a second light emitting element OLED2 including an anode electrode connected to the fourth node N4 and may be disposed in a second pixel row L2. The second subpixel SPb may further include a switch transistor ST21 which is connected to the data line DL and the third node N3 and is turned on or off based on a second scan signal SCANb, a switch transistor ST22 which is connected to the reference voltage line RL and the fourth node N4 and is turned on or off based on the second scan signal SCANb, a second coupling capacitor Cpr2 which is connected to the data line DL and the third node N3, and a second storage capacitor Cst2 which is connected to the third node N3 and the fourth node N4.

The first subpixel SPa and the second subpixel SPb may share the data line DL and the reference voltage line RL.

The data line DL may transfer a first data voltage Vdata1 to the first node N1 through the switch transistor ST11 in a first gate-source voltage setting period Tgs1 corresponding to an on period of the first scan signal SCANa and may transfer a second data voltage Vdata2 to the third node N3 through the switch transistor ST21 in a second gate-source voltage setting period Tgs2 corresponding to an on period of the second scan signal SCANb.

The reference voltage line RL may transfer the first initialization voltage VpreR1 to the second node N2 through the switch transistor ST12 in the first gate-source voltage setting period Tgs1 and may transfer the second initialization voltage VpreR2 to the fourth node N4 through the switch transistor ST22 in the second gate-source voltage setting period Tgs2.

When a second light emitting element OLED2 is degraded more than a first light emitting element OLED1, the second initialization voltage VpreR2 may be greater than the first initialization voltage VpreR1. Accordingly, VRR flicker and an over-emission phenomenon occurring in the second subpixel SPb may be improved.

When a capacitance of the first coupling capacitor Cpr1 is set to 0.1% to 0.5% of a capacitance of the first storage capacitor Cst1, a VRR flicker improvement effect of the first subpixel SPa may increase.

Likewise, when a capacitance of the second coupling capacitor Cpr2 is set to 0.1% to 0.5% of a capacitance of the second storage capacitor Cst2, a VRR flicker improvement effect of the second subpixel SPb may increase.

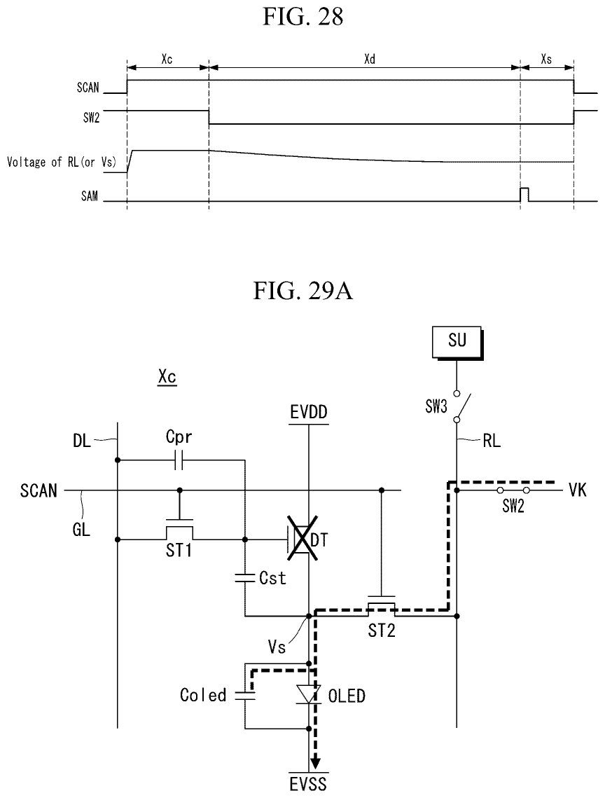

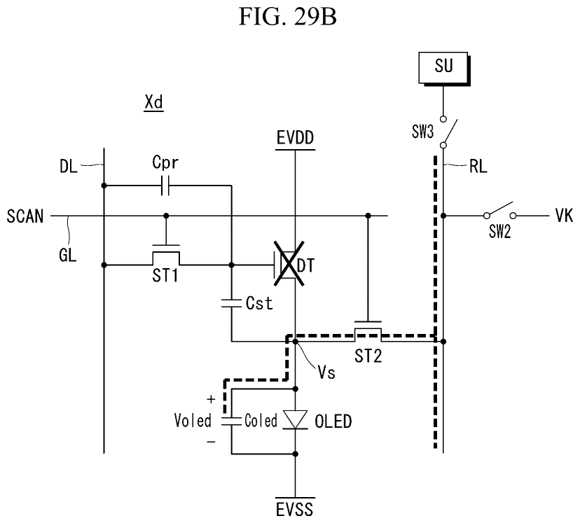

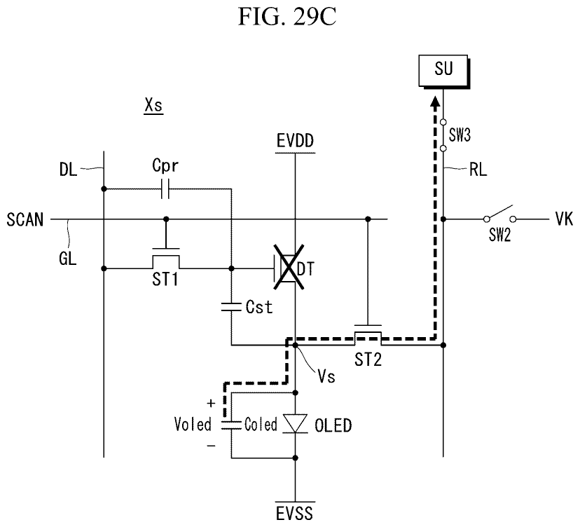

FIG. 28 is a driving waveform diagram for sensing a degradation in an OLED. FIGS. 29A, 29B, and 29C are diagrams illustrating a subpixel operation in a charge period, a discharge period, and a sensing period, respectively.

Referring to FIG. 28, an OLED degradation sensing sequence may be performed in a power on sequence or a power off sequence where display driving is not performed. Referring to FIG. 28, the OLED degradation sensing sequence may include a charge period Xc, a discharge period Xd, and a sensing period Xs.

Referring to FIG. 29A, in the charge period Xc, a tracking voltage VK for sensing an OLED degradation may be applied to an anode electrode of a light emitting element OLED through a switch SW2 and a switch transistor ST2. The tracking voltage VK applied to the anode electrode of the light emitting element OLED may become a source voltage Vs. The tracking voltage VK may be sufficiently higher than a turn on voltage of the light emitting element OLED, and thus, a driving current Ioled may flow through the light emitting element OLED after a Coled is charged. A voltage charged in the Coled may be a threshold voltage of the light emitting element OLED for turning on the light emitting element OLED. As the light emitting element OLED is degraded, the threshold voltage of the light emitting element OLED may increase.

Referring to FIG. 29B, in the discharge period Xd, a switch SW2 may be turned off, and thus, discharging may be performed in the light emitting element OLED. A discharge operation may be performed until an electric potential of a reference voltage line RL is equal to an electric potential of the Coled (i.e., the threshold voltage of the light emitting element OLED). When the electric potential of the reference voltage line RL is equal to the electric potential of the Coled, a discharge operation based on the light emitting element OLED may stop. In the discharge period Xd, the threshold voltage of the light emitting element OLED may be a Voled stored in the Coled.

Referring to FIG. 29C, in the sensing period Xs, a switch SW3 may be turned on, and thus, the Coled may be connected to a sensing circuit SU through a switch transistor ST2 and the switch SW3. The sensing circuit SU may sample the threshold voltage Voled of the light emitting element OLED stored in the Coled.

In an example, a control circuit may include the flicker compensation circuit. In an example, the control circuit may include, or may be, the timing controller 130. In an example, the control circuit may include, or may be, the timing controller 130 and the source driver 110. In an example, the control circuit may include, or may be, the timing controller 130 and the source driver 110. In an example, the control circuit may include, or may be, the timing controller 130, the source driver 110, and the level shifter 140. In an example, a control circuit may include the flicker compensation circuit. In an example, the timing controller 130 may include the flicker compensation circuit.

In one or more examples, a display apparatus may include a subpixel including a driving transistor DT and a light emitting element OLED connected to the driving transistor, a data line DL coupled to the subpixel and configured to apply a data voltage to the subpixel in a gate-source setting period, a reference voltage line RL coupled to the subpixel and configured to apply an initialization voltage VpreR to the subpixel in the gate-source setting period, and a control circuit coupled to the subpixel, configured to determine a degradation of the light emitting element OLED or another light emitting element, and configured to adjust the initialization voltage based on the degradation.

In one or more examples, to determine the degradation, the control circuit may, in a sensing period, sense a threshold voltage stored in an internal capacitor of the light emitting element or the another light emitting element, the sensing period may be different from the gate-source setting period, and display driving is not performed during the sensing period.

In one or more examples, the control circuit may increase the initialization voltage when the degradation increases.

In one or more examples, the control circuit may determine the degradation of the light emitting element of the subpixel and a degradation of a second light emitting element of a second subpixel, and the control circuit may provide the initialization voltage at a first level to the subpixel and a second initialization voltage at a second level to the second subpixel.

In one or more examples, the control circuit may sense the degradation of the light emitting element of the subpixel independently from sensing the degradation of the second light emitting element of the second subpixel, and the control circuit may adjust the initialization voltage to the first level independently from adjusting the second initialization voltage to the second level.

In one or more examples, to determine the degradation, the control circuit may predict the degradation based at least on an accumulated emission history of the light emitting element or the another light emitting element.

In one or more examples, the subpixel may further comprise a storage capacitor coupled to the driving transistor and a coupling capacitor coupled to the data line.

In one or more examples, a capacitance of the coupling capacitor is 0.1% to 0.5% of a capacitance of the storage capacitor.

Embodiments of the present disclosure may realize the following effects.

One or more aspects of the present disclosure may increase a voltage level of an initialization voltage as a light emitting element is degraded. Accordingly, one or more aspects of the present disclosure may decrease a low grayscale recognition luminance deviation occurring in a rapid change condition of a frame frequency to improve VRR flicker and abnormal flashing, thereby enhancing display quality.

The effects according to the present disclosure are not limited to the above examples, and other various effects may be included in the specification.

The description herein has been presented to enable any person skilled in the art to make, use and practice the technical features of the present disclosure, and has been provided in the context of one or more particular example applications and their example requirements. Various modifications, additions and substitutions to the described embodiments will be readily apparent to those skilled in the art, and the principles described herein may be applied to other embodiments and applications without departing from the scope of the present disclosure. The description herein and the accompanying drawings provide non-limiting examples of the technical features of the present disclosure for illustrative purposes. In other words, the disclosed embodiments illustrate the scope of the technical features of the present disclosure and are not intended to be limiting in any respect. Thus, the scope of the present disclosure is not limited to the embodiments shown, but is to be accorded the widest scope consistent with the claims and their equivalents.

What is claimed is:

1. A display apparatus, comprising:
a subpixel including a driving transistor having a gate electrode connected to a first node and a source electrode connected to a second node, a light emitting element having an anode electrode connected to the second node, and a storage capacitor having one electrode connected to the first node and another electrode connected to the second node;
a data line configured to transfer a data voltage to the first node in a gate-source setting period; and
a reference voltage line configured to transfer an initialization voltage to the second node in the gate-source setting period,
wherein a voltage level of the initialization voltage increases as the light emitting element is degraded.

2. The display apparatus of claim 1, wherein, when a degradation sensing value of the light emitting element based on threshold voltage sensing of the light emitting element increases from a first value to a second value,
a level of the initialization voltage has a first voltage level, based on the degradation sensing value of the first value, and has a second voltage level which is higher than the first voltage level, based on the degradation sensing value of the second value.

3. The display apparatus of claim 1, wherein, when a degradation prediction value of the light emitting element based on an accumulated emission history of the light emitting element increases from a first value to a second value,
a level of the initialization voltage has a first voltage level, based on the degradation prediction value of the first value, and has a second voltage level which is higher than the first voltage level, based on the degradation prediction value of the second value.

4. The display apparatus of claim 1, further comprising a coupling capacitor having one electrode connected to the first node and another electrode connected to the data line.

5. The display apparatus of claim 4, wherein a capacitance of the coupling capacitor is 0.1% to 0.5% of a capacitance of the storage capacitor.

6. A display apparatus, comprising:
a first subpixel disposed in a first pixel row and including a first driving transistor having a gate electrode connected to a first node and a source electrode connected to a second node, and a first light emitting element having an anode electrode connected to the second node;
a second subpixel disposed in a second pixel row and including a second driving transistor having a gate electrode connected to a third node and a source electrode connected to a fourth node, and a second light emitting element having an anode electrode connected to the fourth node;
a data line configured to transfer a first data voltage to the first node in a first gate-source setting period and transfer a second data voltage to the third node in a second gate-source setting period; and
a reference voltage line configured to transfer a first initialization voltage to the second node in the first gate-source setting period and transfer a second initialization voltage to the fourth node in the second gate-source setting period,
wherein the first initialization voltage differs from the second initialization voltage.

7. The display apparatus of claim 6, wherein the first subpixel and the second subpixel share the data line and the reference voltage line.

8. The display apparatus of claim 6, wherein, when the second light emitting element is degraded more than the first light emitting element, the second initialization voltage is greater than the first initialization voltage.

9. The display apparatus of claim 6, wherein the first subpixel further comprises a first storage capacitor having one electrode connected to the first node and another electrode connected to the second node, and a first coupling capacitor having one electrode connected to the first node and another electrode connected to the data line, and
wherein the second subpixel further comprises a second storage capacitor having one electrode connected to the third node and another electrode connected to the fourth node, and a second coupling capacitor having one electrode connected to the third node and another electrode connected to the data line.

10. The display apparatus of claim 9, wherein a capacitance of the first coupling capacitor is 0.1% to 0.5% of a capacitance of the first storage capacitor, and
wherein a capacitance of the second coupling capacitor is 0.1% to 0.5% of a capacitance of the second storage capacitor.

11. A display apparatus, comprising:
a subpixel including a driving transistor and a light emitting element connected to the driving transistor;
a data line coupled to the subpixel and configured to apply a data voltage to the subpixel in a gate-source setting period;
a reference voltage line coupled to the subpixel and configured to apply an initialization voltage to the subpixel in the gate-source setting period; and
a control circuit coupled to the subpixel, configured to determine a degradation of the light emitting element or another light emitting element, and configured to adjust the initialization voltage based on the degradation.

12. The display apparatus of claim 11, wherein to determine the degradation, the control circuit is configured to, in a sensing period, sense a threshold voltage stored in an internal capacitor of the light emitting element or the another light emitting element,
wherein the sensing period is different from the gate-source setting period, and
wherein display driving is not performed during the sensing period.

13. The display apparatus of claim 11, wherein the control circuit is configured to increase the initialization voltage when the degradation increases.

14. The display apparatus of claim 11, wherein the control circuit is configured to determine the degradation of the light emitting element of the subpixel and a degradation of a second light emitting element of a second subpixel, and
wherein the control circuit is configured to provide the initialization voltage at a first level to the subpixel and a second initialization voltage at a second level to the second subpixel.

15. The display apparatus of claim 14, wherein the control circuit is configured to sense the degradation of the light emitting element of the subpixel independently from sensing the degradation of the second light emitting element of the second subpixel, and
wherein the control circuit is configured to adjust the initialization voltage to the first level independently from adjusting the second initialization voltage to the second level.

16. The display apparatus of claim 11, wherein to determine the degradation, the control circuit is configured to predict the degradation based at least on an accumulated emission history of the light emitting element or the another light emitting element.

17. The display apparatus of claim 11, wherein the subpixel further comprises a storage capacitor coupled to the driving transistor and a coupling capacitor coupled to the data line.

18. The display apparatus of claim 17, wherein a capacitance of the coupling capacitor is 0.1% to 0.5% of a capacitance of the storage capacitor.
